(19) United States
(12) Patent Application Publication
(10) Pub. No.: US 2021/0010133 A1
(43) Pub. Date: Jan. 14, 2021

(54) METHOD OF MANUFACTURE OF A FILM MADE OF VANADIUM DISULFIDE FILM AND FILM WHICH CAN BE OBTAINED BY THIS METHOD

(71) Applicant: Commissariat à l'énergie atomique et aux énergies alternatives, Paris (FR)

(72) Inventors: Rémy GASSILLOUD, GRENOBLE CEDEX (FR); Stéphane CADOT, GRENOBLE CEDEX (FR); Mathias FRACCAROLI, GRENOBLE CEDEX (FR)

(21) Appl. No.: 16/913,581

(22) Filed: Jun. 26, 2020

(30) Foreign Application Priority Data
Jul. 9, 2019 (FR) 1907688

(51) Int. Cl. C23C 16/30; H01B 1/10; C23C 16/50

(52) U.S. Cl. CPC C23C 16/305; H01B 5/14; C23C 16/50; H01B 1/10

(57) ABSTRACT

A method to manufacture a film made of vanadium disulphide by chemical vapor deposition on a previously heated substrate, includes successive procedures implemented in a vacuum reactor: injection of at least one organometallic molecule of vanadium, where the vanadium has a valence of less than or equal to 4; drainage of the reactor; injection of at least one sulphur molecule including at least one free thiol group, or forming a reaction intermediate comprising at least one free thiol group; injection of a reducing gas.

### TECHNICAL FIELD OF THE INVENTION

The technical field of the invention is that of film manufacturing methods, and more specifically that of methods to manufacture films made of vanadium disulphide.

The present invention concerns a method to manufacture a film, and in particular a method to manufacture a film made of vanadium disulphide. The present invention also concerns a film made of vanadium disulphide obtained by the method.

### TECHNOLOGICAL BACKGROUND OF THE INVENTION

Vanadium disulphide is known for its properties of high conductivity and of high output work. The term “conductivity” is understood to mean the ability of a material to allow the electrical charges to move so as to allow an electric current to pass, and the term “output work” is understood to mean the minimum energy to be given to an electron of a metal to remove it from this metal.

This being so, vanadium disulphide is commonly used as an electrode, and in particular as an electrode in batteries.

Vanadium is traditionally obtained by a solvothermal method which leads to the formation of a fine powder of vanadium disulphide, which is then spread on a substrate to form an electrode.

It is also known to synthesise vanadium disulphide by vacuum chemical deposition, by causing a molecule of vanadium chloride (III) VCl₃ to react with elementary sulphur S in a tube furnace heated to a temperature of between 450° C. and 500° C. The deposit obtained in this manner has disjointed crystalline zones of vanadium sulphide several microns wide.

Regardless of the method of the prior art used, the obtained vanadium disulphide cannot be deposited conformally on a substrate, and is not compatible with a uniform deposition over a large area, for example a circular area with a diameter of the order of 300 mm. The field of application of the vanadium disulphide obtained in this manner is therefore considerably limited.

There is therefore a requirement to synthesise vanadium disulphide which is able to be deposited conformally and in a uniform manner on a substrate of a large area.

### SUMMARY OF THE INVENTION

The invention provides a solution to the problems mentioned above, by enabling a film of vanadium disulphide to be obtained, deposited in a uniform and conformal manner on a substrate having, for example, a circular area with a diameter of the order of 300 mm.

A first aspect of the invention concerns a method to manufacture a film made of vanadium disulphide by chemical vapor deposition on a previously heated substrate, comprising successive steps implemented in a vacuum reactor:
i. Injection of at least one organometallic molecule of vanadium, where the vanadium has a valence of less than or equal to 4;
ii. Draining of the reactor;
iii. Injection of at least one sulphur molecule comprising at least one free thiol group, or forming a reaction intermediate comprising at least one free thiol group;
iv. Injection of a reducing gas.

By virtue of the invention the organometallic vanadium molecule is attached to the substrate, and then reacts with the sulphur molecule to form a film of vanadium disulphide. The fact that the reactor is under a vacuum enables the sulphur molecule to be prevented from being contaminated by dioxygen in the air. Injecting dihydrogen enables the surface nucleation sites to be reactivated, so that the growth of the film can continue if required, by repeating the method. Draining guarantees that the gases will not mix, to limit the formation of powders. At the end of the method the substrate is uniformly covered with a film of vanadium disulphide which retains its properties of high conductivity and high output work, and which is conformal with the surface of the substrate, which can be larger or smaller. In addition, the film obtained in this manner is transparent, and is therefore compatible with optical applications such as, for example, use as a conducting electrode for screens. The expression “the film is transparent” is understood to mean that the film deposited on a transparent substrate has a transmittance greater than or equal to 50% for a given wavelength, and for a given thickness, and the expression “transparent substrate” is understood to mean a substrate with a transmittance greater than or equal to 50% for a given wavelength.

In addition to the characteristics mentioned in the previous paragraph, the method according to a first aspect of the invention can have one or more additional characteristics of the following kinds, considered individually or in all technically possible combinations.

According to one variant implementation, steps i. to iv. are repeated multiple times.

Thus, in the first cycle, the organometallic vanadium molecule is attached to the substrate, and then reacts with the sulphur molecule to form a vanadium disulphide film, and during the following cycle is the organometallic vanadium molecule is attached to the surface of the previously created film, and then reacts with the sulphur molecule, causing the vanadium disulphide film to grow.

According to one variant implementation compatible with the previous variant implementation, the substrate is heated to a temperature of between 100° C. and 250° C.

The temperature of the substrate enables the reactions to be accelerated without burning the molecules.

According to one variant implementation compatible with the previous variant implementations, the organometallic vanadium molecule is injected pure.

According to one variant implementation compatible with the previous variant implementations except for the previous variant implementation, the organometallic vanadium molecule is injected diluted in a solvent.

Fewer organometallic vanadium molecules are thus injected with each cycle.

According to one variant implementation compatible with the previous variant implementations, the organometallic vanadium molecule is chosen from among the following molecules: tetrakis(ethylmethylamino)vanadium(IV) TEMAV, tetrakis(dimethylamido)vanadium(IV) TDMAV, tetrakis(diethylamino)vanadium(IV) TDEAV, vanadium tetrachloride VCl₄, vanadium (III) chloride VCl₃, vanadium bromide VBr₃, the molecules bearing a cyclopentadienyl functional group and/or bearing a carbonyl functional group, or the halogenated molecules of valence of less than or equal to 4.

The organometallic vanadium molecule is thus at most of valence IV, meaning that there is no requirement for a reducing step after the method to obtain a film made of vanadium disulphide.

According to one variant implementation compatible with the previous variant implementations, drainage is accomplished by means of a flow of an inert gas.

According to one variant implementation compatible with the previous variant implementations, the sulphur molecule is chosen from among the following molecules: ethanedithiol EDT, hydrogen sulphide H₂S, dimethyl disulphide DMDS, diethyl disulphide DEDS, dipropyl disulphide DPDS, dibenzyl disulphide DBDS, di-tert-butyl disulphide DTBDS.

According to one variant implementation compatible with the previous variant implementations, the sulphur molecule is blended with dihydrogen.

According to one variant implementation compatible with the previous variant implementations, the sulphur molecule is injected pure.

According to one variant implementation compatible with the previous variant implementations except for the previous variant implementation, the sulphur molecule is injected in a blend with an inert carrier gas.

Fewer sulphur molecules are thus injected with each cycle.

According to one variant implementation compatible with the previous variant implementations, the sulphur molecule is injected with a reducing plasma.

The grafting time of the sulphur molecule is reduced by this means.

According to one variant implementation compatible with the previous variant implementations, the injected reducing gas is dihydrogen.

According to one variant implementation compatible with the previous variant implementations, the reducing gas is injected pure.

According to one variant implementation compatible with the previous variant implementations except for the previous variant implementation, the reducing gas is injected in a blend with an inert carrier gas.

Less reducing gas is thus injected with each cycle.

According to one variant implementation compatible with the previous variant implementations, the step of injection of the reducing gas comprises a sub-step of dihydrogen-based reducing plasma treatment.

The overall time of the method is reduced by this means.

According to one variant implementation compatible with the previous variant implementations, the surface of the substrate is prepared by means of a flow of a reducing gas.

By this means the residual oxygen and the moist condensates are eliminated from the reactor, enabling the reaction to be accelerated.

According to one sub-variant implementation compatible with the previous sub-variant implementation, preparation of the surface of the substrate comprises a sub-step of plasma treatment.

The overall time of the method is reduced by this means.

According to one sub-variant implementation compatible with the previous sub-variant implementations, preparation of the surface of the substrate comprises a sub-step of exposure to a sulphur molecule.

Formation of the substrate-sulphur links is facilitated by this means.

According to one variant implementation compatible with the previous variant implementations, the method comprises a step of drainage of the reactor between the step of injection of the sulphur molecule and the step of injection of dihydrogen.

A second aspect of the invention concerns a film made of vanadium disulphide which may be obtained by the method according to a first aspect of the invention, characterised by the fact that, when deposited on a substrate having a transmittance greater than 50% for a wavelength of between 450 and 2750 nm, the film has a transmittance higher than 50% for a wavelength of between 450 and 2750 nm.

The film obtained is thus transparent.

According to a variant implementation, the film has a roughness of less than 0.3 nm.

According to a variant implementation, the film is deposited conformally on the substrate.

The invention and its various applications will be better understood on reading the description which follows, and on examining the figures which accompany it.

### BRIEF DESCRIPTION OF THE FIGURES

The figures are given for information only, and are not restrictive of the invention in any manner.

FIG. 1 shows a block diagram representing the sequencing of the steps of a manufacturing method according to a first aspect of the invention.

FIG. 2 shows a diagrammatic representation of a film according to a second aspect of the invention, obtained by the method according to a first aspect of the invention.

FIG. 3 is a graph illustrating the transmittance percentage as a function of the wavelength in nanometres for a substrate and for a film according to a second aspect of the invention, which is 6 nm thick, deposited on the substrate.

FIG. 4 is a graph illustrating the current in unified atomic mass units as a function of the energy in electronvolts for the atomic orbital of nitrogen, obtained by X-ray photoelectron spectrometry on the film according to a second aspect of the invention, with or without a step of thermal crystallisation.

### DETAILED DESCRIPTION

Unless otherwise stipulated, a given element shown in different figures has a single reference.

A first aspect of the invention concerns a method of manufacture of a film made of vanadium disulphide of chemical formula VS₂, and a second aspect of the invention concerns a film made of vanadium disulphide obtained by the method according to a first aspect of the invention.

The term “film” is understood to mean a thin layer of material covering a surface, for example of the order of several nanometres thick.

FIG. 2 shows a diagrammatic representation of film 200 according to a second aspect of the invention, obtained by the method according to a first aspect of the invention.

The method according to a first aspect of the invention is implemented in a vacuum reactor 202. The volume of reactor 202 is generally less than 5 litres. The pressure in reactor 202 is, for example, 2 Torr. According to one implementation, all steps of the method are implemented in this vacuum reactor 202.

The method according to a first aspect of the invention is chemical vapor deposition, or CVD, on a substrate 201.

Substrate 201 is, for example, silicon Si, silicon dioxide SiO₂, silicon carbide SiC, sapphire Al₂O₃, an oxide of the transition metals, such as TiO₂, ZrO₂, HfO₂, VO₂, V₂O₅, NbO₂, Nb₂O₅, Ta₂O₅, MoOₓ, WOₓ, SnO₂, InₓSn_{y}O_{z}, ZnO, CuOₓ, NiOₓ, ZnO AlₓZn_{y}O_{z}, GaₓZn_{y}O_{z} or AlₓGa_{y}Zn_{z}O_{w}, aluminium nitride AlN, gallium nitride GaN, titanium nitride TiN, tungsten W, a sulphide or selenide or tellurium of the transition metals, TiS₂, ZrS₂, HfS₂, NbS₂, TaS₂, MoS₂, WS₂, ZnS, SnS₂, NiSₓ, InSₓ, GaSₓ, InₓGa_{y}S_{z}, TiSe₂, ZrSe₂, HfSe₂, NbSe₂, TaSe₂, MoSe₂, WSe₂, ZnSe, InSeₓ, GaSeₓ, NiSeₓ, InₓNi_{y}Se_{z}InₓGa_{y}Se_{z}, TiTe₂, ZrTe₂, HfTe₂, NbTe₂, TaTe₂, MoTe₂, WTe₂, ZnTe, or a chalcogenide, CdTe, CdₓZn_{y}Te_{z}, GeTe, GeₓSb_{y}Te_{z}, GeₓN_{y}Te_{z}, where x, y and z are natural integers.

Substrate 201 is transparent, i.e. it has a transmittance greater than or equal to 50% for a given wavelength.

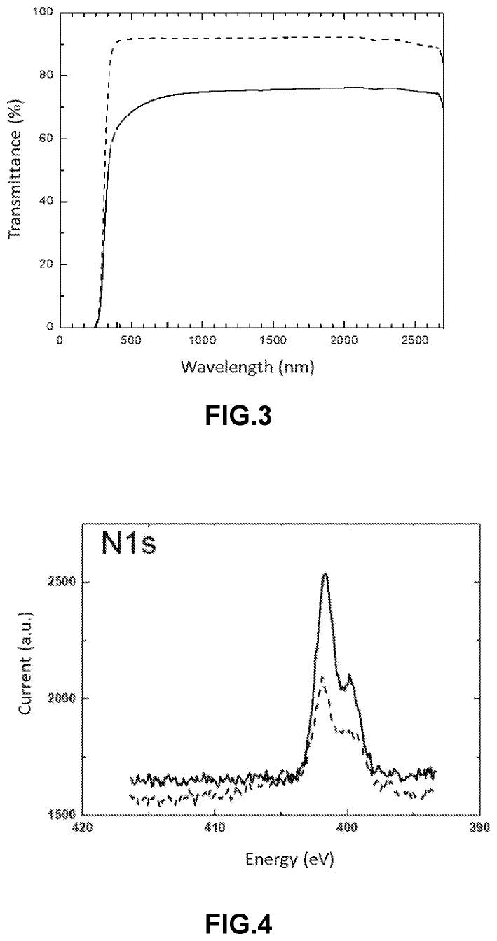

FIG. 3 For example, in FIG. 3, substrate 201 is made of borosilicate and has a transmittance of greater than 80% for a wavelength of between 300 and 2700 nm.

Substrate 201 is previously heated, for example to a temperature of between 100° C. and 250° C.

The surface of substrate 201 can be previously prepared to facilitate the reactions, and in particular to remove the moist condensates, for example by gas flow. The gas used is a reducing gas, for example dihydrogen H₂, dinitrogen N₂ or argon Ar. Substrate 201 is prepared, for example, after substrate 201 is heated.

Substrate 201 can also be prepared with using a plasma treatment to reduce the overall time to implement the method. Substrate 201 is prepared using a plasma treatment, for example, after substrate 201 is prepared by gas flow.

The preparation of substrate 201 can also comprise a sub-step of exposure of the surface of substrate 201 to a sulphur molecule. This sulphur molecule is, for example, identical to the one which will be injected in reactor 202 in a step described below, called the third step, of the method according to a first aspect of the invention.

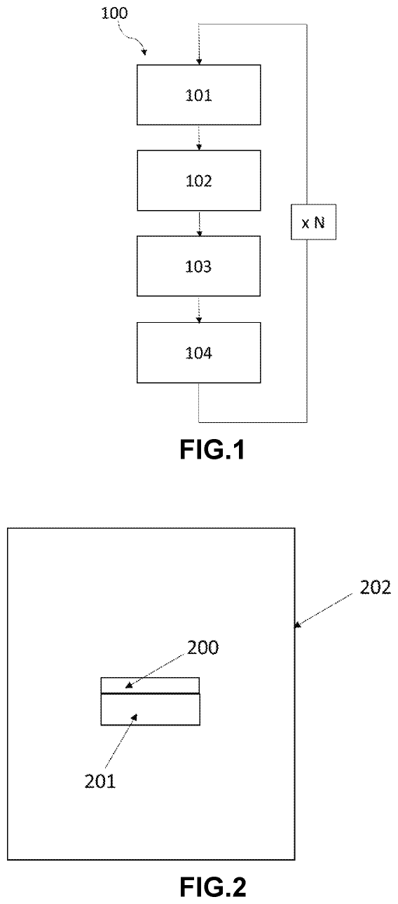

FIG. 1 shows a block diagram representing the sequencing of the steps of method 100 according to a first aspect of the invention.

Steps 101 to 104 of method 100 according to a first aspect of the invention are implemented at least once, i.e. method 100 according to a first aspect of the invention comprises at least one cycle.

A first step 101 of method 100 according to a first aspect of the invention consists in injecting at least one organometallic molecule of vanadium in reactor 202. In other words, first step 101 consists in injecting a component comprising at least one organometallic molecule of vanadium in reactor 202, where the component is, for example, a gas.

The term “organometallic molecule” is understood to mean a molecule comprising at least one carbon atom and a core metal. An organometallic molecule can, for example, also include at least one nitrogen atom linked directly with the core metal; this is the case in particular with metal amides.

In the remainder of the description the term “organometallic molecule of vanadium” refers to a molecule comprising carbon atoms and a vanadium atom as the core metal.

In the organometallic molecule of vanadium the vanadium has a valence of between 1 and 4. The term “valence” is understood to mean the number of covalent links which an atom has formed in a molecule.

The organometallic molecule of vanadium is, for example, tetrakis(ethylmethylamino)vanadium(IV) TEMAV, tetrakis(dimethylamido)vanadium(IV) TDMAV, tetrakis(diethylamino)vanadium(IV) TDEAV, vanadium bromide VBr₃, the molecules comprising vanadium and bearing a cyclopentadienyl functional group and/or bearing a carbonyl functional group, for example bis(cyclopentadienyl)vanadium, vanadium hexacarbonyl V(CO)₆ or, alternatively, vanadium tetracarbonyl cyclopentadienide. The halogenated organometallics can also be used with a valence of less than or equal to 4 with vanadium, for example Bis(cyclopentadienyl)vanadium dichloride.

The organometallic molecule of vanadium can also be vanadium tetrachloride VCl₄ or vanadium(III) chloride VCl₃.

Method 100 according to a first aspect of the invention can also function for an organometallic molecule of vanadium in which the vanadium has a valence which is strictly higher than 4 if a step of reduction is implemented on film 200 finally obtained by method 100 to lower the stoichiometry of film 200 and obtain a disulphide. This step of reduction is, for example, implemented using a dihydrogen-based reducing plasma.

The organometallic molecule of vanadium can be injected pure or diluted in an organic solvent. For example, the organic solvent may have a saturating vapour pressure higher than the organometallic molecule, such that the organic solvent evaporates without interacting on film 200. The organic solvent is, for example, octane or cyclohexane. The organometallic molecule is, for example, diluted to 0.1 mole/litre in the organic solvent.

The duration of the injection of the organometallic molecule of vanadium 101 depends on the speed at which the organometallic molecule of vanadium is grafted on substrate 201 in a first cycle, or on the surface of the film generated in the previous cycle for following cycles. In general, the duration of first step 101 is less than 2 seconds.

The optimal duration of first step 101 is, for example, obtained after a finite number of cycles, after a saturation curve representing the speed of growth of the cycle as a function of grafting time of the organometallic molecule reaches a threshold.

A second step 102 of method 100 according to a first aspect of the invention consists in draining reactor 202.

Second step 102 of method 100 according to a first aspect of the invention is, for example, implemented by a flow of inert gas.

Second step 102 of method 100 according to a first aspect of the invention is, for example, implemented by successive steps of vacuum suction and of refilling reactor 202 with inert gas. The number of steps of vacuum suction and refilling with inert gas is, for example, chosen to ensure that the organometallic molecule is eliminated from reactor 202.

The inert gas used is, for example, dinitrogen N₂, argon Ar, or helium He.

The duration of second step 102 depends on the geometry of reactor 202 and on its pumping capacity. For a reactor 202 with a volume of less than 5 litres and a “primary” pump, the duration of second step 102 is less than 2 seconds.

The optimal duration of second step 102 is, for example, obtained after a finite number of cycles, after a saturation curve representing the speed of growth of the cycle as a function of drainage time reaches a threshold.

A third step 103 of method 100 according to a first aspect of the invention consists in injecting at least one sulphur molecule.

The term “sulphur molecule” is understood to mean a molecule comprising at least one sulphur atom. According to a first implementation, the sulphur molecule comprises at least one free thiol group. A thiol is a group of generic formula R—SH where R is an organic residue and SH the sulfhydryl group.

According to a second implementation, the sulphur molecule forms a reaction intermediate comprising at least one free thiol group. The term “reaction intermediate” is understood to mean a species participating in a reaction mechanism which is neither a reagent nor a product of the reaction.

The sulphur molecule is, for example, ethanedithiol EDT, hydrogen sulphide H₂S, dimethyl disulphide DMDS, diethyl disulphide DEDS, dipropyl disulphide DPDS, dibenzyl disulphide DBDS or di-tert-butyl disulphide DTBDS. The sulphur molecule can be blended with dihydrogen H₂.

Third step 103 of method 100 according to a first aspect of the invention can be implemented using a reducing plasma.

The sulphur molecule can be injected pure or blended with dihydrogen H₂ and/or blended with an inert carrier gas. The inert carrier gas is, for example, dinitrogen N₂ or argon Ar or helium He.

The duration of third step 103 depends on the grafting speed of the sulphur molecule. In general, the duration of third step 103 is less than 2 seconds.

Third step 103 of method 100 according to a first aspect of the invention can be followed by a step of drainage of reactor 202. This step of draining of reactor 202 can be identical to second step 102 of draining of reactor 202, and enables the reaction to be accelerated whilst ensuring separation of the chemical processes.

A fourth step 104 of method 100 according to a first aspect of the invention consists in injecting a reducing gas in reactor 202. The reducing gas is, for example, dihydrogen H₂.

The reducing gas can be injected pure or blended with an inert carrier gas. The inert carrier gas is, for example, dinitrogen N₂, argon Ar or helium He.

Fourth step 104 of method 100 according to a first aspect of the invention can comprise a sub-step of treatment of substrate 200 by a reducing plasma. The reducing plasma is, for example, based on dihydrogen H₂. This sub-step of treatment of substrate 200 enables the overall time of method 100 to be reduced.

Steps 101 to 104 of method 100 are, for example, undertaken at a temperature of lower than 250° C.

As illustrated in FIG. 1, steps 101 to 104 of method 100 according to a first aspect of the invention are implemented N times in order to attain the desired thickness. N is, for example, between 1 and 10⁵ cycles. The number of cycles N is adjusted as a function of the growth speed per cycle to attain the desired thickness.

With each cycle the thickness of film 200 of vanadium disulphide increases. The growth speed is between 0.5 and 2 Angstöm per cycle. Film 200 is then 10 nm thick after some one hundred cycles.

On conclusion of method 100, film 200 is, for example, between 6 and 10 nm thick.

Film 200 obtained in this manner has a resistivity of less than 1500 μΩ·cm, a roughness of less than 0.3 nm and output work of higher than 4.6 eV.

The term “roughness of the film” is understood to mean the absolute value of the maximum height difference between an irregularity of the surface of the film and a theoretical surface line. The roughness is therefore a surface roughness.

In addition, as illustrated in FIG. 3, film 200 deposited on substrate 201, and then annealed at 450° C., has a transmittance of greater than 60% for a wavelength of between 300 and 2700 nm and is 6 nm thick, which means that film 200 is transparent, although it can be observed that deposition of film 200 on transparent substrate 201 causes transmittance to be reduced.

As can be seen in FIG. 3, film 200 deposited on substrate 201 has a transmittance of greater than 50% for a wavelength of between 350 and 2700 nm, a transmittance greater than 60% for a wavelength of between 400 and 2700 nm, a transmittance greater than 70% for a wavelength of between 650 and 2700 nm and a transmittance of greater than 75% for a wavelength of between 1100 and 2700 nm.

It should be noted that the thickness of film 200 is constant across its entire surface; with this method 100 a film 200 is therefore obtained the deposit of which is conformal.

Resistivity is defined as the reverse of conductivity.

To improve the characteristics of film 200 of vanadium disulphide, i.e. to obtain a film with a lower resistivity, a lower roughness and a higher output work, a step of thermal crystallisation can be implemented after fourth step 104 of method 100 according to a first aspect of the invention.

The step of thermal crystallisation consists, for example, of annealing at 450° C. for 10 minutes in argon Ar. Another example is a thermal treatment at 950° C. under a flow of ethanedithiol EDT, leading to complete crystallisation of the film.

After this step of thermal crystallisation, film 200 obtained in this manner has a resistivity of less than 500 μΩ·cm, a roughness of less than 0.2 nm and output work of higher than 5 eV.

It can be demonstrated that a film 200 according to a second aspect of the invention has been obtained by method 100 according to a first aspect of the invention, by undertaking X-ray photoelectron spectrometry of film 200.

FIG. 4 is a graph illustrating the current in unified atomic mass units a.u. as a function of the energy in electronvolts eV for the atomic orbital of nitrogen N1s, obtained by X-ray photoelectron spectrometry on film 200.

A peak representing the state of the links with nitrogen in film 200 is observed, showing that there are nitrogen residues in film 200. Thus, if film 200 has been obtained by using an organometallic molecule of vanadium amine such as TEMAV, for example, X-ray photoelectron spectrometry undertaken for the orbital of nitrogen will enable nitrogen residues to be identified.

Similarly, if film 200 has been obtained by using a chlorinated organometallic molecule of vanadium, X-ray photoelectron spectrometry undertaken for the orbital of chlorine will enable chlorine residues to be identified, and if film 200 has been obtained using a brominated organometallic molecule of vanadium, an X-ray photoelectron spectrometry undertaken for the orbital of bromine will enable bromine residues to be identified.

In FIG. 4, the dashed line curve concerns a film 200 obtained with a step of thermal crystallisation, and the continuous line curve concerns a film 200 obtained without a step of thermal crystallisation.

The step of thermal recrystallisation also therefore enables the quantity of residues in film 200 to be reduced.

Alternatively, or in combination, it can be demonstrated that a film 200 has been obtained by method 100 according to the invention, by observing by scanning electron microscopy that the deposit of the film is conformal, i.e. that it has the same thickness over its entire surface. When making this observation it is also possible to check that the film is indeed closed, i.e. not porous or only slightly porous.

Alternatively, or in combination, it is possible to demonstrate that a film 200 has been obtained by method 100 according to the invention by performing X-ray reflectometry (XRR), showing that the film has a roughness of less than 0.3 nm, regardless of the deposited thickness.

1. A film made of vanadium disulphide intended to be deposited on a substrate with a transmittance of over 50% for a wavelength of between 450 and 2750 nm, having a transmittance of over 50% for a wavelength of between 450 and 2750 nm, wherein the film has a surface roughness of less than 0.3 nm, where the surface roughness is measured by X-ray reflectometry.

2. The film according to claim 1, wherein the film is intended to be deposited conformally on the substrate.

3. The film according to claim 1, wherein the film is between 6 and 10 nm thick.

4. The film according to claim 1, wherein the film has a transmittance of over 60% for a wavelength of between 450 and 2750 nm.

5. A method of manufacture of a film made of vanadium disulphide according to claim 1, by chemical vapor deposition on a substrate, comprising a step of heating of the substrate and successive steps implemented in a vacuum reactor:
i. injecting at least one organometallic molecule of vanadium, where the vanadium has a valence of less than or equal to 4;
ii. draining the reactor;
iii. injecting at least one sulphur molecule comprising at least one free thiol group, or forming a reaction intermediate comprising at least one free thiol group;
iv. injecting a reducing gas.

6. The method of manufacture according to claim 5, wherein the steps i. to iv. are repeated multiple times.

7. The method of manufacture according to claim 5, wherein the steps i. to iv. are undertaken at a temperature of lower than 250° C.

8. The method of manufacture according to claim 5, wherein the substrate is heated to a temperature of between 100° C. and 250° C.

9. The method of manufacture according to claim 5, wherein the organometallic molecule of vanadium is chosen from among the following molecules: tetrakis(ethylmethylamino)vanadium TEMAV, tetrakis(dimethylamido)vanadium TDMAV, tetrakis(diethylamino)vanadium TDEAV, vanadium bromide VBr3, the molecules bearing a cyclopentadienyl functional group and/or bearing a carbonyl functional group, or the halogenated molecules of valence of less than or equal to 4.

10. The method of manufacture according to claim 5, wherein the organometallic molecule of vanadium is vanadium tetrachloride VCl₄ or vanadium chloride VCl₃.

11. The method of manufacture according to claim 5, wherein the sulphur molecule is chosen from among the following molecules: ethanedithiol EDT, hydrogen sulphide H₂S, dimethyl disulphide DMDS, diethyl disulphide DEDS, dipropyl disulphide DPDS, dibenzyl disulphide DBDS, di-tert-butyl disulphide DTBDS.

12. The method of manufacture according to claim 5, wherein the sulphur molecule is blended with dihydrogen.

13. The method of manufacture according to claim 5, wherein the injected reducing gas is dihydrogen.

14. The method of manufacture according to claim 5, wherein the step of injection of a reducing gas comprises a sub-step of hydrogen-based reducing plasma treatment.

15. The method of manufacture according to claim 5, wherein a surface of the substrate is prepared by a flow of reducing gas.

16. The method of manufacture according to claim 15, wherein the surface preparation of the substrate comprises a sub-step of plasma treatment.

17. The method of manufacture according to claim 15, wherein the surface preparation of the substrate comprises a sub-step of exposure to a sulphur molecule.

18. The method of manufacture according to claim 5, further comprising draining the reactor between the step of injection of the molecule including at least one free thiol and the step of injection of a reducing gas, where the reducing gas is dihydrogen.

19. The method of manufacture according to claim 5, wherein the step of injection of the organometallic molecule of vanadium comprises a step of injection of a component including the organometallic molecule of vanadium.
